(19) United States
(12) Patent Application Publication
(10) Pub. No.: US 2026/0047044 A1
(43) Pub. Date: Feb. 12, 2026

(54) LIQUID SUPPLY DEVICE AND LIQUID PUMPING SYSTEM INCLUDING THE SAME

(71) Applicant: DELTA ELECTRONICS, INC., Taoyuan City (TW)

(72) Inventors: Chih-Chieh LU, Taoyuan City (TW); Hsuan-Yi PAN, Taoyuan City (TW); Kuan-Hsun WANG, Taoyuan City (TW)

(21) Appl. No.: 19/201,964

(22) Filed: May 8, 2025

(30) Foreign Application Priority Data
Aug. 8, 2024 (CN) 202421906396.1

(51) Int. Cl. H05K 7/20

(52) U.S. Cl. CPC H05K 7/20272

(57) ABSTRACT

A liquid supply device includes a liquid storage tank and at least one liquid pipe. The liquid storage tank includes a housing and a partition. The housing has an accommodation space, an inlet and at least one outlet. The partition is disposed in the accommodation space and divides the accommodation space into a first space and a second space. The inlet communicates with the first space, and the outlet communicates with the second space. The second space is of greater volume than the first space. The partition has at least two openings through which the first space and the second space communicate with each other. The liquid pipe is connected to at least one of the inlet and the outlet of the housing.

### RELATED APPLICATIONS

This application claims priority to China Application Serial Number 202421906396.1, filed Aug. 8, 2024, the disclosure of which is incorporated herein by reference in its entirety.

### BACKGROUND

### Technical Field

The present disclosure relates to a liquid supply device and a liquid pumping system including the same.

### Description of Related Art

A liquid cooling system typically includes a water tank. When water flows into the water tank, the liquid level in the water tank would fluctuate, making it difficult to accurately determine the liquid level. In addition, the water flowing into the water tank could impact the sidewalls of the water tank, resulting in formation of bubbles. If the pump of the system receives these bubbles, the reliability of the pump could decrease.

### SUMMARY

In view of the foregoing, one of the objects of the present disclosure is to provide a liquid supply device and a liquid pumping system that can suppress fluctuation of the liquid level of the liquid coolant in the liquid storage tank.

To achieve the objective stated above, in accordance with an embodiment of the present disclosure, a liquid supply device includes a liquid storage tank and at least one liquid pipe. The liquid storage tank includes a housing and a partition. The housing has an accommodation space, an inlet and at least one outlet. The partition is disposed in the accommodation space and divides the accommodation space into a first space and a second space. The inlet communicates with the first space, and the outlet communicates with the second space. The second space is of greater volume than the first space. The partition has at least two openings through which the first space and the second space communicate with each other. The liquid pipe is connected to at least one of the inlet and the outlet of the housing.

In one or more embodiments of the present disclosure, the partition has a first opening and a second opening which are placed at different heights.

In one or more embodiments of the present disclosure, the housing includes a first wall portion and a second wall portion opposite to the first wall portion. The first wall portion is at a higher position than the second wall portion. The first opening of the partition is adjacent to the first wall portion, and the second opening of the partition is adjacent to the second wall portion.

In one or more embodiments of the present disclosure, the partition further has a first edge abutting against the first wall portion of the housing. The first opening of the partition is a notch on the first edge.

In one or more embodiments of the present disclosure, the partition further has a second edge abutting against the second wall portion of the housing. The second opening of the partition is a notch on the second edge.

In one or more embodiments of the present disclosure, the liquid supply device further includes a filter disposed at the inlet of the liquid storage tank.

In one or more embodiments of the present disclosure, the liquid supply device further includes a sensor disposed in the housing and located in the second space. The sensor is configured to sense a liquid pressure or a liquid level of a liquid in the liquid storage tank.

In accordance with an embodiment of the present disclosure, a liquid supply device includes a liquid storage tank, a sensor and at least one liquid pipe. The liquid storage tank includes a housing and a partition. The housing has an accommodation space, an inlet and at least one outlet. The partition is disposed in the accommodation space and divides the accommodation space into a first space and a second space. The inlet and the outlet communicate with the second space. The partition has at least two openings through which the first space and the second space communicate with each other. The sensor is disposed in the first space of the housing and is configured to sense a liquid pressure or a liquid level of a liquid in the liquid storage tank. The liquid pipe is connected to at least one of the inlet and the outlet of the housing.

In accordance with an embodiment of the present disclosure, a liquid pumping system includes the liquid supply device described above and at least one liquid pump. The liquid pump is connected to the outlet of the liquid storage tank via the liquid pipe of the liquid supply device.

In one or more embodiments of the present disclosure, the liquid pumping system includes a plurality of liquid pumps and further includes a liquid distribution device connected to the liquid pumps.

In sum, in the liquid pumping system of the present disclosure, the liquid storage tank is provided with a partition. The partition divides the accommodation space of the liquid storage tank into a first space and a second space. The first space and the second space communicate with the inlet and the outlet of the liquid storage tank, respectively. The second space is of greater volume than the first space. The partition has at least two openings through which the first space and the second space communicate with each other. By this arrangement, fluctuation of the liquid level of the liquid coolant in the liquid storage tank can be suppressed, enabling accurate measurement of liquid level and/or liquid pressure in the liquid storage tank. Moreover, formation of bubbles can be suppressed such that the liquid pump connected to the liquid storage tank can be prevented from receiving bubbles. As a result, reliability of the liquid pump is improved.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates a schematic top view of a liquid pumping system in accordance with an embodiment of the present disclosure;

FIG. 2 illustrates a schematic exploded view of the liquid storage tank of the liquid pumping system shown in FIG. 1;

FIG. 3 illustrates a schematic top view of the liquid storage tank of the liquid pumping system shown in FIG. 1, with a lid of the liquid storage tank being removed;

FIG. 4A illustrates a schematic sectional view of the liquid storage tank shown in FIG. 1 near the top of the partition;

FIG. 4B illustrates a schematic sectional view of the liquid storage tank shown in FIG. 1 near the bottom of the partition;

FIG. 5 illustrates a schematic top view of a liquid storage tank in accordance with another embodiment of the present disclosure; and

FIG. 6 illustrates a schematic top view of a liquid storage tank in accordance with another embodiment of the present disclosure.

### DETAILED DESCRIPTION

For the completeness of the description of the present disclosure, reference is made to the accompanying drawings and the various embodiments described below. Various features in the drawings are not drawn to scale and are provided for illustration purposes only. To provide full understanding of the present disclosure, various practical details will be explained in the following descriptions. However, a person with an ordinary skill in relevant art should realize that the present disclosure can be implemented without one or more of the practical details. Therefore, the present disclosure is not to be limited by these details.

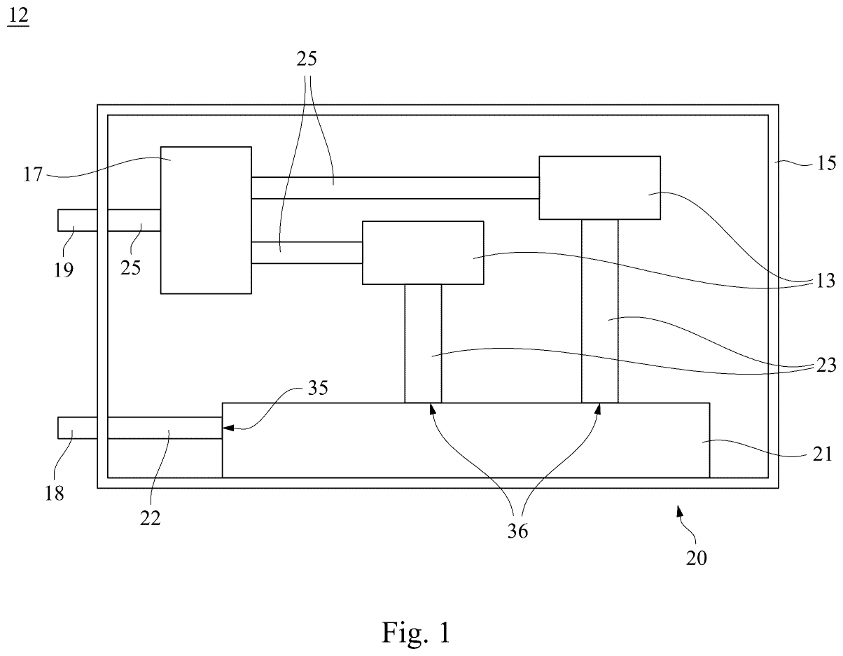

Reference is made to FIG. 1. FIG. 1 illustrates a schematic top view of a liquid pumping system 12 in accordance with an embodiment of the present disclosure. The liquid pumping system 12 may be incorporated as part of a cooling system for an electronic device or system (e.g., personal computer, server, or data center). The liquid pumping system 12 is configured to drive a liquid coolant (not depicted; for example, the liquid coolant can be water) to flow and make heat exchange with at least one heat source in the electronic device or system to control the temperature of the heat source.

As shown in FIG. 1, the liquid pumping system 12 includes a liquid supply device 20 and at least one liquid pump 13. The liquid supply device 20 is connected to an inlet 18 of the liquid pumping system 12. After the liquid coolant enters the liquid pumping system 12 via the inlet 18, the liquid coolant is temporarily stored in the liquid supply device 20 and would later be supplied to the liquid pump 13. The liquid pump 13 is connected to the liquid supply device 20 and is configured to receive the liquid coolant from the liquid supply device 20. The liquid pump 13 can increase the pressure of the liquid coolant and output the liquid coolant via at least one outlet 19 of the liquid pumping system 12.

As shown in FIG. 1, the liquid supply device 20 includes a liquid storage tank 21 and at least one liquid pipe 23. The liquid storage tank 21 is configured to store the liquid coolant. The liquid pump 13 is connected to the liquid storage tank 21 via the liquid pipe 23 to acquire the liquid coolant from the liquid storage tank 21. Furthermore, the liquid storage tank 21 can be connected to the inlet 18 of the liquid pumping system 12 via another liquid pipe 22.

As shown in FIG. 1, in some embodiments, the liquid pumping system 12 includes a plurality of liquid pumps 13. The liquid pumps 13 can acquire the liquid coolant from the liquid storage tank 21 via a plurality of different liquid pipes 23 and then output the liquid coolant with higher pressure. In some embodiments, the liquid pumping system 12 further includes a liquid distribution device 17. The liquid distribution device 17 is connected to the liquid pumps 13 and at least one outlet 19 of the liquid pumping system 12. The liquid distribution device 17 is configured to receive the liquid coolant from the liquid pumps 13 and distribute the liquid coolant to the at least one outlet 19 of the liquid pumping system 12. In the illustrated embodiment, the liquid pumping system 12 has a single outlet 19, and the liquid distribution device 17 is configured to merge the liquid coolant output by the liquid pumps 13 and direct the liquid coolant to the single outlet 19 of the liquid pumping system 12. The liquid distribution device 17 can be connected to the liquid pumps 13 and the outlet 19 via a plurality of liquid pipes 25.

As shown in FIG. 1, in some embodiments, the liquid pumping system 12 further includes a casing 15. The liquid pumps 13, the liquid distribution device 17 and the liquid supply device 20 of the liquid pumping system 12 are disposed in the casing 15. The inlet 18 and the outlet 19 of the liquid pumping system 12 can be provided on a sidewall of the casing 15.

In some embodiments, thee inlet 18 and the outlet 19 of the liquid pumping system 12 can be connected to an external pipeline (not depicted), and the liquid pumping system 12 can form a loop with the external pipeline. The external pipeline can be thermally coupled to at least one heat source (not depicted) such that when the liquid coolant passes through the external pipeline, the liquid coolant can absorb heat from the heat source and bring heat away from the heat source. The external pipeline can be thermally coupled to the heat source by directly making contact with the heat source. Alternatively, the external pipeline can be thermally coupled to the heat source via one or more thermally conductive components, such as heatsink, heat pipe, metal block, thermal pad, other suitable thermally conductive components, or any combination thereof.

In some embodiments, the liquid pumping system 12 can further include a cooling device (not depicted). The cooling device can be a liquid-to-liquid heat exchanger or a liquid-to-gas heat exchanger. The cooling device is configured to cool the liquid coolant after the liquid coolant is heated by the heat source, such that the liquid coolant be reused and circulated. In other embodiments, the liquid pumping system 12 does not necessarily have to include the cooling device. For example, the cooling device can alternatively be included as part of the external pipeline connected to the liquid pumping system 12.

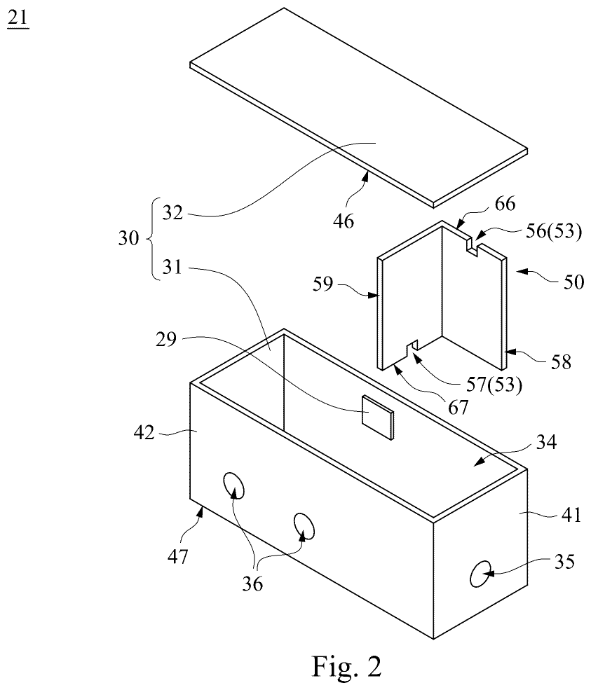

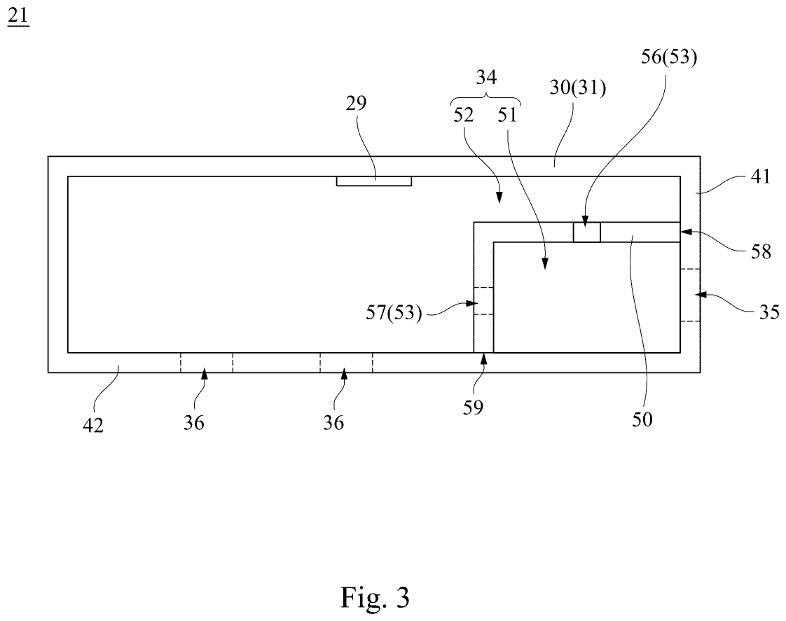

Reference is made to FIGS. 2 and 3. FIG. 2 illustrates a schematic exploded view of the liquid storage tank 21 of the liquid pumping system 12 shown in FIG. 1. FIG. 3 illustrates a schematic top view of the liquid storage tank 21 of the liquid pumping system 12 shown in FIG. 1, with a lid of the liquid storage tank 21 being removed. As shown, the liquid storage tank 21 includes a housing 30. The housing 30 has an accommodation space 34 for storing the liquid coolant. The housing 30 further has an inlet 35 and at least one outlet 36. The inlet 35 and the at least one outlet 36 are in fluid communication with the accommodation space 34. The liquid pipe 22 mentioned above can be connected between the inlet 35 of the housing 30 and the inlet 18 of the liquid pumping system 12. The liquid pipe 23 mentioned above can be connected between the outlet 36 of the housing 30 and an inlet of the liquid pump 13.

As shown in FIGS. 2 and 3, in some embodiments, the inlet 35 and the outlet 36 are provided on a sidewall of the housing 30 and penetrate through the sidewall of the housing 30. In some embodiments, the inlet 35 and the outlet 36 are provided on two different sides of the sidewall of the housing 30. For example, the sidewall of the housing 30 can include a first wall 41 and a second wall 42 adjoining the first wall 41. The inlet 35 can be provided on the first wall 41, and the outlet 36 can be provided on the second wall 42.

As shown in FIGS. 2 and 3, in some embodiments, the housing 30 include multiple housing components that are assembled to form the housing 30. For example, in the illustrated embodiment, the housing 30 includes a first housing component 31 and a second housing component 32. The first housing component 31 can be a box with a top opening. The second housing component 32 can be a lid covering the top opening of the first housing component 31.

As shown in FIGS. 2 and 3, the liquid storage tank 21 further includes a partition 50. The partition 50 is disposed in the accommodation space 34 of the housing 30 and divides the accommodation space 34 into a first space 51 and a second space 52. The inlet 35 of the housing 30 communicates with the first space 51. Hence, when the liquid coolant enters the housing 30 via the inlet 35, the liquid coolant first enters the first space 51. The outlet 36 of the housing 30 communicates with the second space 52. Hence, the liquid coolant stays in the second space 52 before leaving the housing 30. In other words, the partition 50 is inserted between the inlet 35 and the outlet 36 of the housing 30. In other words, the partition 50 separates the inlet 35 from the outlet 36. Moreover, the second space 52 is of greater volume than the first space 51.

As shown in FIGS. 2 and 3, the partition 50 has at least one opening 53 through which the first space 51 and the second space 52 communicate with each other. In other words, the liquid coolant can flow between the first space 51 and the second space 52 via the at least one opening 53 of the partition 50. The at least one opening 53 can include structure such as a notch, a through hole or a slit of the partition 50. A characteristic size of each of the at least one opening 53 (e.g., a width, height, or area of the opening 53) is smaller than a characteristic size of the housing 30. For example, an area of each of the at least one opening 53 is smaller than an area of the inlet 35 of the housing 30.

By virtue of the structural configuration described above, the liquid storage tank 21 of the present disclosure can suppress fluctuation of the liquid level of the liquid coolant stored therein, as well as suppress formation of bubbles. Specifically, when the liquid coolant first enters the housing 30 via the inlet 35, the liquid coolant is confined in the first space 51 of smaller volume. The liquid coolant in the first space 51 is injected into the second space 52 under the control of the opening 53 having a small size. Hence, in the second space 52, fluctuation of the liquid level is small, and the liquid coolant contains few or no bubbles. Accordingly, accurate measurement of the liquid level and/or the liquid pressure in the liquid storage tank 21 can be attained. Moreover, the liquid pump 13 connected to the liquid storage tank 21 can be prevented from receiving bubbles, and thus the reliability of the liquid pump 13 is improved.

As shown in FIGS. 2 and 3, in some embodiments, the liquid supply device 20 further includes at least one sensor 29 disposed in the housing 30 and located in the second space 52. The at least one sensor 29 can include a pressure sensor configured to sense a liquid pressure of the liquid coolant in the liquid storage tank 21. The at least one sensor 29 can also include a liquid level sensor configured to sense or detect the liquid level of the liquid coolant in the liquid storage tank 21. As mentioned above, with the partition 50, fluctuation of the liquid level in the second space 52 is small. Hence, installing the sensor 29 in the second space 52 of the housing 30 can enable accurate measurement of liquid level and/or liquid pressure in the liquid storage tank 21.

As shown in FIGS. 2 and 3, in some embodiments, the partition 50 has two lateral edges 58 and 59. The two lateral edges 58 and 59 are located on two opposite sides of the partition 50, and they both abut against the sidewall of the housing 30. In some embodiments, the two lateral edges 58 and 59 of the partition 50 abut against the first wall 41 and the second wall 42 of the sidewall of the housing 30, respectively, such that the first space 51 is created at a corner of the accommodation space 34.

As shown in FIGS. 2 and 3, in some embodiments, the at least one opening 53 of the partition 50 includes a first opening 56 and a second opening 57 placed at different heights. In some embodiments, the housing 30 includes a first wall portion 46 and a second wall portion 47 opposite to the first wall portion 46. When the housing 30 is in the upright configuration as shown in FIG. 2, the first wall portion 46 is at a higher position than the second wall portion 47. For example, the first wall portion 46 can be an upper cover or lid of the housing 30 (i.e., the second housing component 32 includes the first wall portion 46), and the second wall portion 47 can be the bottom of the housing 30. The sidewall of the housing 30, where the inlet 35 and the outlet 36 are provided, is connected between the first wall portion 46 and the second wall portion 47. The first opening 56 of the partition 50 is adjacent to the first wall portion 46, and the second opening 57 of the partition 50 is adjacent to the second wall portion 47. In some embodiments, the first opening 56 and the second opening 57 being placed at different heights means that when the housing 30 is in the upright configuration as shown in FIG. 2 (the first wall portion 46 on the top, the second wall portion 47 at the bottom, and the inlet 35 and the outlet 36 on lateral sides), heights of the first opening 56 and the second opening 57 measured from the bottom of the housing 30 (e.g., the second wall portion 47) are different. In some embodiments, the first opening 56 and the second opening 57 have different vertical position in a vertical direction normal to the second wall portion 47. In some embodiments, the first opening 56 is at a first distance away from the second wall portion 47, the second opening 57 is at a second distance away from the second wall portion 47, and the first distance is greater than the second distance.

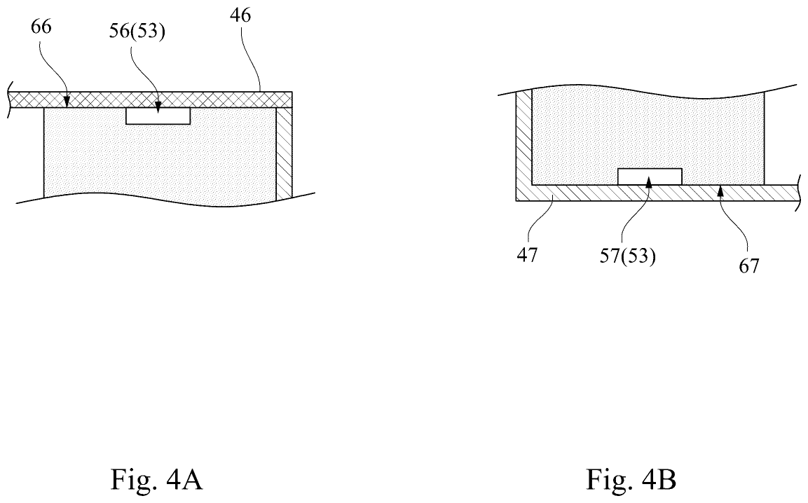

Reference is made additionally to FIG. 4A. FIG. 4A illustrates a schematic sectional view of the liquid storage tank 21 shown in FIG. 1 near the top of the partition 50. As shown in FIGS. 2, 3 and 4A, in some embodiments, the partition 50 further has a first edge 66 abutting against the first wall portion 46 of the housing 30, and the first opening 56 of the partition 50 is a notch on the first edge 66.

Reference is made additionally to FIG. 4B. FIG. 4B illustrates a schematic sectional view of the liquid storage tank 21 shown in FIG. 1 near the bottom of the partition 50. As shown in FIGS. 2, 3 and 4B, in some embodiments, the partition 50 further has a second edge 67 abutting against the second wall portion 47 of the housing 30, and the second opening 57 of the partition 50 is a notch on the second edge 67.

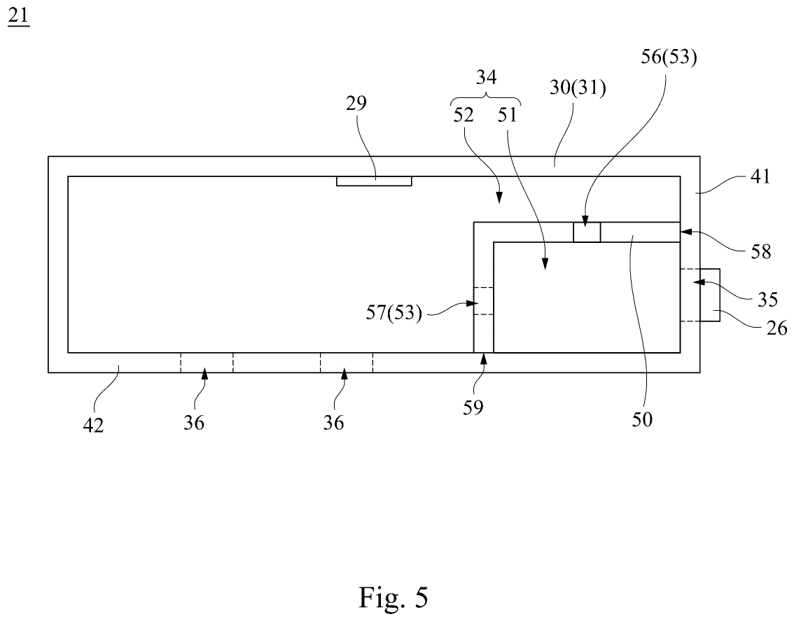

Reference is made to FIG. 5. FIG. 5 illustrates a schematic top view of a liquid storage tank 21 in accordance with another embodiment of the present disclosure. In the present embodiment, the liquid supply device further includes a filter 26 disposed at the inlet 35 of the housing 30 of the liquid storage tank 21. The filter 26 has tiny pores that can stabilize the liquid coolant passing through the filter 26. Hence, the filter 26 can help further suppress fluctuation of the liquid level in the liquid storage tank 21, as well as suppress formation of bubbles. The filter 26 can be disposed on an outer side of the inlet 35 of the housing 30 as shown in FIG. 5. The filter 26 can be provided at other suitable locations as well. For example, the filter 26 can be disposed on an inner side of the inlet 35 of the housing 30, or the filter 26 can extend through the inlet 35 of the housing 30.

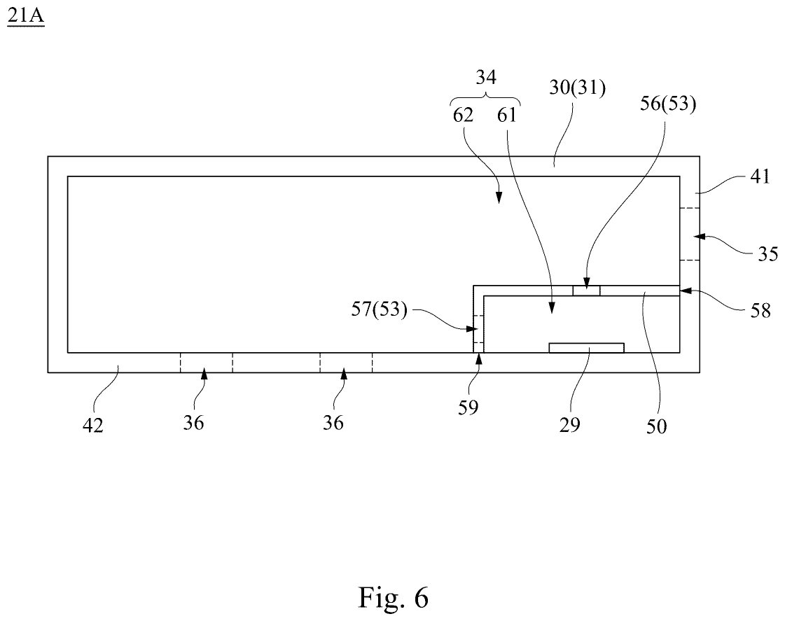

Reference is made to FIG. 6. FIG. 6 illustrates a schematic top view of a liquid storage tank 21A in accordance with another embodiment of the present disclosure. The present embodiment differs from the embodiments described above in that the inlet 35 and the outlet 36 of the housing 30 of the liquid storage tank 21A both communicate with the second space 62 of the housing 30, and the sensor 29 is disposed in the first space 61 of the housing 30. In other words, the partition 50 is inserted between the sensor 29 and the inlet 35 and the outlet 36 of the housing 30. In other words, the partition 50 separates the sensor 29 from the inlet 35 and the outlet 36 of the housing 30. As a result, fluctuation of liquid level in the first space 61 is small, enabling accurate measurement of liquid level and/or liquid pressure.

The structure of the partition 50 of the liquid storage tank 21A of the present embodiment can be generally the same as that of the partition 50 of the previous embodiments. The partition 50 can have a first opening 56 at a higher position and a second opening 57 at a lower position. When the liquid level is lower than the first opening 56, the liquid coolant can flow between the first space 61 and the second space 62 via the second opening 57, such that the liquid level in the first space 61 can stably increase. When the liquid level reaches the height of the first opening 56, the first opening 56 can act as a discharge port that allows some liquid coolant in the first space 61 to return to the second space 62. In some embodiments, the second opening 57 is located on a side of the partition 50 away from the inlet 35 of the housing 30. In other words, the second opening 57 of the partition 50 faces away from the inlet 35 of the housing 30.

In sum, in the liquid pumping system of the present disclosure, the liquid storage tank is provided with a partition. The partition divides the accommodation space of the liquid storage tank into a first space and a second space. The first space and the second space communicate with the inlet and the outlet of the liquid storage tank, respectively. The second space is of greater volume than the first space. The partition has at least two openings through which the first space and the second space communicate with each other. By this arrangement, fluctuation of the liquid level of the liquid coolant in the liquid storage tank can be suppressed, enabling accurate measurement of liquid level and/or liquid pressure in the liquid storage tank. Moreover, formation of bubbles can be suppressed such that the liquid pump connected to the liquid storage tank can be prevented from receiving bubbles. As a result, reliability of the liquid pump is improved.

Although the present disclosure has been described by way of the exemplary embodiments above, the present disclosure is not to be limited to those embodiments. Any person skilled in the art can make various changes and modifications without departing from the spirit and the scope of the present disclosure. Therefore, the protective scope of the present disclosure shall be the scope of the claims as attached.

What is claimed is:

1. A liquid supply device, comprising:
a liquid storage tank comprising a housing and a partition, wherein the housing has an accommodation space, an inlet and at least one outlet, the partition is disposed in the accommodation space and divides the accommodation space into a first space and a second space, wherein the inlet communicates with the first space, the at least one outlet communicates with the second space, the second space is of greater volume than the first space, wherein the partition has at least two openings through which the first space and the second space communicate with each other; and
at least one liquid pipe connected to at least one of the inlet and the at least one outlet.

2. The liquid supply device of claim 1, wherein the at least two openings comprise a first opening and a second opening placed at different heights.

3. The liquid supply device of claim 2, wherein the housing comprises a first wall portion and a second wall portion opposite to the first wall portion, the first wall portion is at a higher position than the second wall portion, wherein the first opening of the partition is adjacent to the first wall portion, and the second opening of the partition is adjacent to the second wall portion.

4. The liquid supply device of claim 3, wherein the partition further has a first edge abutting against the first wall portion of the housing, and the first opening of the partition is a notch on the first edge.

5. The liquid supply device of claim 3, wherein the partition further has a second edge abutting against the second wall portion of the housing, and the second opening of the partition is a notch on the second edge.

6. The liquid supply device of claim 1, further comprising a filter disposed at the inlet of the liquid storage tank.

7. The liquid supply device of claim 1, further comprising a sensor, wherein the sensor is disposed in the housing and is located in the second space, the sensor is configured to sense a liquid pressure or a liquid level of a liquid in the liquid storage tank.

8. A liquid pumping system, comprising:
the liquid supply device of claim 1; and
at least one liquid pump connected to the at least one outlet of the liquid storage tank via the at least one liquid pipe of the liquid supply device.

9. The liquid pumping system of claim 8, further comprising a liquid distribution device, wherein the at least one liquid pump is plural in number, and the liquid distribution device is connected to the liquid pumps.

10. The liquid pumping system of claim 8, wherein the at least two openings of the partition comprise a first opening and a second opening placed at different heights.

11. The liquid pumping system of claim 10, wherein the housing comprises a first wall portion and a second wall portion opposite to the first wall portion, the first wall portion is at a higher position than the second wall portion, wherein the partition further has a first edge abutting against the first wall portion of the housing, and the first opening of the partition is a notch on the first edge, wherein the partition further has a second edge abutting against the second wall portion of the housing, and the second opening of the partition is a notch on the second edge.

12. A liquid supply device, comprising:
a liquid storage tank comprising a housing and a partition, wherein the housing has an accommodation space, an inlet and at least one outlet, the partition is disposed in the accommodation space and divides the accommodation space into a first space and a second space, wherein the inlet and the at least one outlet communicate with the second space, wherein the partition has at least two openings through which the first space and the second space communicate with each other;
a sensor disposed in the first space of the housing and configured to sense a liquid pressure or a liquid level of a liquid in the liquid storage tank; and
at least one liquid pipe connected to at least one of the inlet and the at least one outlet.

13. The liquid supply device of claim 12, wherein the at least two openings comprise a first opening and a second opening placed at different heights.

14. The liquid supply device of claim 13, wherein the housing comprises a first wall portion and a second wall portion opposite to the first wall portion, the first wall portion is at a higher position than the second wall portion, wherein the first opening of the partition is adjacent to the first wall portion, and the second opening of the partition is adjacent to the second wall portion.

15. The liquid supply device of claim 14, wherein the partition further has a first edge abutting against the first wall portion of the housing, and the first opening of the partition is a notch on the first edge.

16. The liquid supply device of claim 14, wherein the partition further has a second edge abutting against the second wall portion of the housing, and the second opening of the partition is a notch on the second edge.

17. The liquid supply device of claim 12, further comprising a filter disposed at the inlet of the liquid storage tank.

18. A liquid pumping system, comprising:
the liquid supply device of claim 12; and
at least one liquid pump connected to the at least one outlet of the liquid storage tank via the at least one liquid pipe of the liquid supply device.

19. The liquid pumping system of claim 18, further comprising a liquid distribution device, wherein the at least one liquid pump is plural in number, and the liquid distribution device is connected to the liquid pumps.

20. The liquid pumping system of claim 18, wherein the at least two openings of the partition comprise a first opening and a second opening placed at different heights.
